(19) United States
(12) Patent Application Publication
(10) Pub. No.: US 2026/0324055 A1
(43) Pub. Date: Oct. 15, 2026

(54) SEMICONDUCTOR DEVICE

(71) Applicant: FUJI ELECTRIC CO., LTD., Kanagawa (JP)

(72) Inventors: Naoko KODAMA, Matsumoto-city (JP); Akira TAMENORI, Matsumoto-city (JP); Yoshihisa SUZUKI, Matsumoto-city (JP)

(21) Appl. No.: 19/685,084

(22) Filed: May 22, 2026

Related U.S. Application Data
(63) Continuation of application No. PCT/JP2025/017440, filed on May 13, 2025.

(30) Foreign Application Priority Data
Jun. 13, 2024 (JP) 2024-095597

(51) Int. Cl. H10D 84/00; H10D 62/10; H10D 62/53; H10D 84/01; H10P 32/10

(52) U.S. Cl. CPC H10D 84/161; H10D 62/127; H10D 62/53; H10D 84/0109; H10P 32/18

(57) ABSTRACT

A semiconductor device is provided that includes a plurality of transistor portions and a plurality of diode portions alternately arranged, a plurality of trench portions extending in a predetermined trench extending direction on a front surface of a semiconductor substrate, an emitter electrode provided above the front surface of the semiconductor substrate, and a protective layer provided above the emitter electrode, in which the semiconductor device includes a protective structure in which a plurality of protective regions in which the protective layer is provided and a plurality of opening regions in which the protective layer is not provided are alternately provided.

The contents of the following patent application(s) are incorporated herein by reference:
NO. 2024-095597 filed in JP on Jun. 13, 2024
NO. PCT/JP2025/017440 filed in WO on May 13, 2025.

### BACKGROUND

### 1. Technical Field

The present invention relates to a semiconductor device.

### 2. Related Art

Conventionally, a semiconductor device provided with a protective film such as polyimide has been known (see, for example, Patent Documents 1 to 3).

### RELATED ART DOCUMENTS

### Patent Documents

Patent Document 1: Japanese patent application publication No. 2009-38140
Patent Document 2: Japanese patent application publication No. 2015-177116
Patent Document 3: Japanese patent application publication No. 2015-26683

### BRIEF DESCRIPTION OF THE DRAWINGS

FIG. 1 is a diagram illustrating an example of an upper surface of a semiconductor device 100.

FIG. 2 is an enlarged top view of the region A in FIG. 1.

FIG. 3 is a diagram illustrating the cross section a-a of FIG. 2.

FIG. 4A is a top view illustrating an arrangement example of the protective layer 150.

FIG. 4B is a diagram illustrating the cross section b1-b1 of FIG. 4A.

FIG. 4C is a diagram illustrating the cross section b2-b2 of FIG. 4A.

FIG. 5A is a top view illustrating another arrangement example of the protective layer 150.

FIG. 5B is a diagram illustrating the cross section c1-c1 of FIG. 5A.

FIG. 5C is a diagram illustrating the cross section c2-c2 of FIG. 5A.

FIG. 6A is a top view illustrating another arrangement example of the protective layer 150.

FIG. 6B is a diagram illustrating the cross section d1-d1 of FIG. 6A.

FIG. 6C is a diagram illustrating the cross section d2-d2 of FIG. 6A.

FIG. 7 is a flowchart illustrating an example of the manufacturing process of the semiconductor device 100.

FIG. 8 is a diagram illustrating an example in which step S110 in FIG. 7 is applied to the cross section a-a of FIG. 2.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. Of the two main surfaces of the substrate, the layer, or another member, one surface is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as a depth direction. In addition, in the present specification, a direction parallel to the front surface and the back surface of the semiconductor substrate may be referred to as a horizontal direction, including the X axis and the Y axis.

A region from a center in the depth direction of the semiconductor substrate to the front surface of the semiconductor substrate may be referred to as a front surface side. Similarly, the region from the center in the depth direction of the semiconductor substrate to the back surface of the semiconductor substrate may be referred to as a back surface side.

When a term such as “same” or “equal” is used herein, it may encompass a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor presenting a conductivity type of the N type, or a semiconductor presenting a conductivity type of the P type.

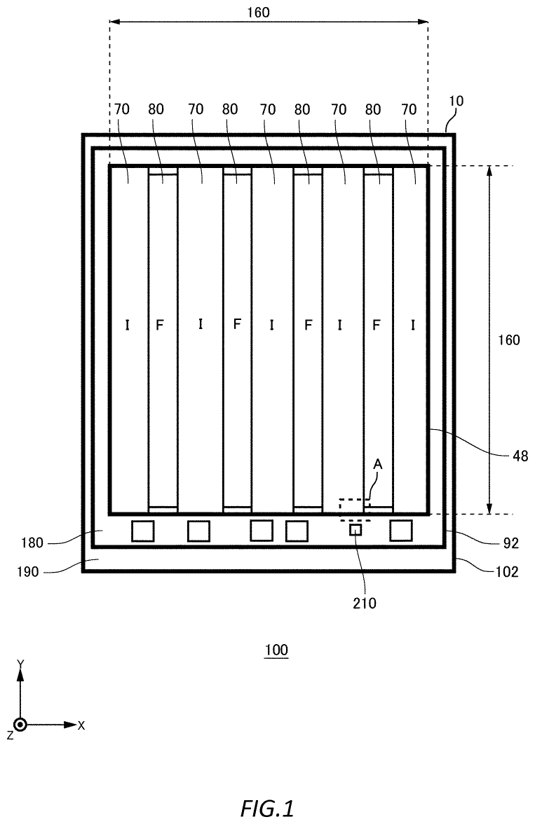

FIG. 1 is a diagram illustrating an example of the upper surface of the semiconductor device 100. FIG. 1 shows a position at which each member is projected on a front surface of a semiconductor substrate 10. FIG. 1 shows merely some members of the semiconductor device 100, and omits illustrations of some members.

The semiconductor device 100 includes the semiconductor substrate 10. The semiconductor substrate 10 has an end side 102 in the top view. When merely referred to as the top view in the present specification, it means that the semiconductor substrate 10 is viewed from a front surface side. The semiconductor substrate 10 of the present example includes two sets of end sides 102 facing each other in the top view. In FIG. 1, the X axis and the Y axis are parallel to any of the end sides 102. In addition, the Z axis is perpendicular to the front surface of the semiconductor substrate 10.

The semiconductor substrate 10 has the active region 160, the outer peripheral region 180, and the edge termination region 190. The active region 160 refers to a region where main currents flow in the depth direction between the front surface and the back surface of the semiconductor substrate 10, when the semiconductor device 100 is operated. Above the active region 160, an emitter electrode is provided, but it is omitted in FIG. 1.

The active region 160 is provided with at least one of a transistor portion 70 including a transistor element such as an IGBT or a diode portion 80 including a diode element such as a freewheeling diode (FWD). In the example of FIG. 1, the plurality of transistor portions 70 and the plurality of diode portions 80 are alternately arranged in stripes on the front surface of the semiconductor substrate 10 along a predetermined element arrangement direction (the X axis direction in the present specification). In another example, in the active region 160, the diode portions 80 may be arranged in the lattice pattern in the transistor portion 70.

A temperature sensing portion, which is the PN junction diode formed of polysilicon or the like, may be provided in a central portion of the active region 160.

In FIG. 1, a region where each of the transistor portions 70 is arranged is indicated by a symbol “I”, and a region where each of the diode portions 80 is arranged is indicated by a symbol “F”. In the present specification, the direction perpendicular to the element arrangement direction in the top view may be referred to as the element extending direction (the Y axis direction in the present specification). The transistor portion 70 and the diode portion 80 may each have a longitudinal direction in the predetermined trench extending direction. In other words, the length of each of the transistor portions 70 in the Y axis direction is larger than the width in the X axis direction. Similarly, the length of each of the diode portions 80 in the Y axis direction is larger than the width in the X axis direction.

The width of the transistor portion 70 in the X axis direction is greater than the width of the diode portion 80 in the X axis direction. Further, the width of the transistor portion 70 in the X axis direction may be the same as the width of the diode portion 80 in the X axis direction. In one example, the width of the transistor portion 70 in the X axis direction is 1200 μm or more and 1500 μm or less, and the width of the diode portion 80 in the X axis direction is 300 μm or more and 500 μm or less. The element extending direction of the transistor portion 70 and the diode portion 80 and the trench extending direction of each trench portion may be the same. The element arrangement direction of the transistor portion 70 and the diode portion 80 and the trench arrangement direction of each trench portion described later may be the same.

The diode portion 80 has the N+ type cathode region in a region in contact with the back surface of the semiconductor substrate 10. In the present specification, a region where the cathode region is provided is referred to as the diode portion 80. In other words, the diode portion 80 is a region that overlaps with the cathode region in the top view. On the back surface of the semiconductor substrate 10, a P+ type collector region may be provided in a region other than the cathode region. In the present specification, the diode portion 80 may include an extension region in which the diode portion 80 is extended in the Y axis direction to the gate runner described later. The collector region is provided on a lower surface of the extension region.

The transistor portion 70 includes a collector region of the P+ type in a region in contact with the back surface of the semiconductor substrate 10. In addition, in the transistor portion 70, a gate structure having an N+ type emitter region, a P− type base region, the gate conductive portion, and the gate dielectric film is periodically arranged on the front surface side of the semiconductor substrate 10.

The semiconductor device 100 includes the gate runner 48 that electrically connects a conductive portion of a gate trench portion to a gate pad. The gate runner 48 is arranged between the active region 160 and the end side 102 of the semiconductor substrate 10 in the top view. The gate runner 48 of the present example surrounds the active region 160 in the top view. In the top view, the region surrounded by the gate runner 48 may be defined as the active region 160, and the region on the end side 102 side from the gate runner 48 may be defined as the outer peripheral region 180.

The gate runner 48 is arranged above the semiconductor substrate 10. The gate runner 48 of the present example may be formed of polysilicon doped with impurities, or the like. The gate runner 48 is electrically connected to the gate conductive portion provided inside the gate trench portion via a gate dielectric film.

The outer peripheral region 180 surrounds the active region 160 in the top view. The outer peripheral region 180 may have one or more auxiliary pads provided above the semiconductor substrate 10. As an example, the semiconductor device 100 has auxiliary pads such as the anode pad, the cathode pad, and a current detection pad. Each auxiliary pad may be connected to an external circuit via wiring such as a wire.

The outer peripheral region 180 may have the current sensing portion 210. The current sensing portion 210 detects a current flowing through the transistor portion 70. The outer peripheral region 180 may further have a temperature sensing portion and the protection diode that are PN junction diodes formed of polysilicon or the like.

The edge termination region 190 of the present example is arranged between the outer peripheral region 180 and the end side 102. The edge termination region 190 mitigates electric field concentration on the front surface side of the semiconductor substrate 10.

The edge termination region 190 may have the guard ring 92. The guard ring 92 is a region of a P type in contact with the front surface of the semiconductor substrate 10. The edge termination region 190 of the present example has a plurality of guard rings 92, but an omission is made in FIG. 1, and only the single guard ring 92 is illustrated. By providing the plurality of guard rings 92, a depletion layer on the upper surface side of the active region 160 can be extended outward, so that a breakdown voltage of the semiconductor device 100 can be improved. The edge termination region 190 may further include at least one of the field plate or RESURF provided in an annular shape so as to surround the outer peripheral region 180.

The protective layer 150 is provided above the semiconductor substrate 10; however, the protective layer 150 is omitted in FIG. 1. The protective layer 150 is formed of polyimide or the like, and is the protective film that covers the entirety of the front surface side of the semiconductor substrate 10. The protective layer 150 may have opening portions at positions corresponding to the auxiliary pads, the wires, and the like provided in the outer peripheral region 180.

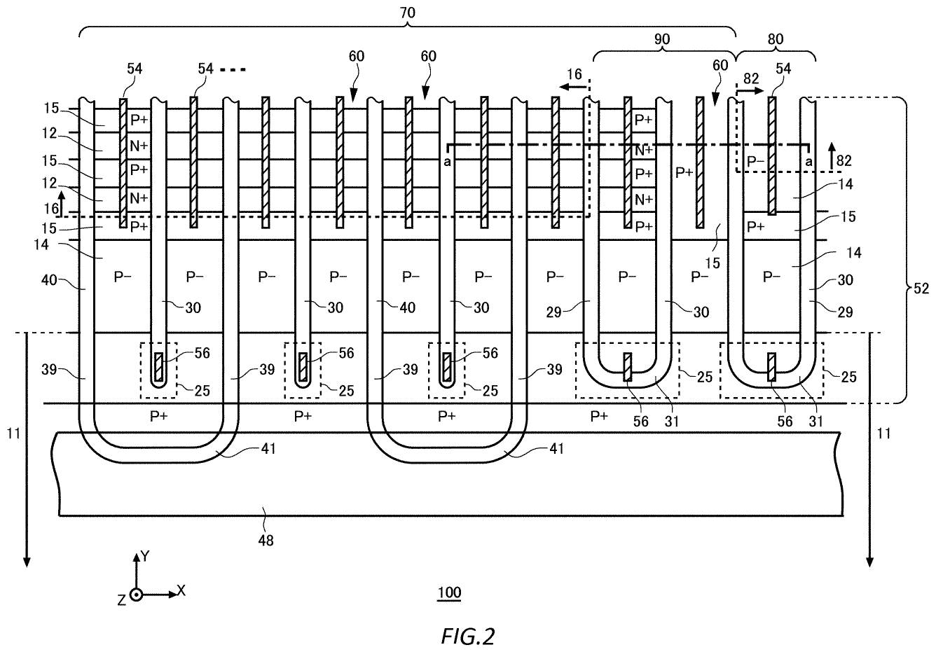

FIG. 2 is the top view in which a region A of FIG. 1 is enlarged. The semiconductor device 100 includes a semiconductor substrate having a transistor portion 70 including a transistor element such as an IGBT and a diode portion 80 including a diode element such as a freewheeling diode (FWD).

The semiconductor device 100 of this example includes the gate trench portion 40, the dummy trench portion 30, the well region 11, the emitter region 12, the base region 14, and the contact region 15 that are provided on the front surface of the semiconductor substrate 10. Each of the gate trench portion 40 and the dummy trench portion 30 is an example of the trench portion.

The semiconductor device 100 of this example further includes the emitter electrode 52 provided above the front surface of the semiconductor substrate 10. The interlayer dielectric film is provided between the emitter electrode 52 and the front surface of the semiconductor substrate 10; however, the interlayer dielectric film is omitted in FIG. 2. In the interlayer dielectric film of this example, contact holes 54 and 56 are provided so as to penetrate the interlayer dielectric film. In FIG. 2, each contact hole is hatched with the diagonal lines.

The emitter electrode 52 is provided above the gate trench portion 40, the dummy trench portion 30, the well region 11, the emitter region 12, the base region 14, and the contact region 15. The emitter electrode 52 is electrically connected to the emitter region 12, the base region 14, and the contact region 15 on the front surface of the semiconductor substrate 10 through the contact holes 54.

In addition, the emitter electrode 52 is connected to a dummy conductive portion in the dummy trench portion 30 through the contact hole 56. Between the emitter electrode 52 and the dummy conductive portion, a connection portion 25 formed of a conductive material such as polysilicon doped with an impurity may be provided. The connection portion 25 is provided on the front surface of the semiconductor substrate 10 via dielectric films such as the interlayer dielectric film and the dummy dielectric film of the dummy trench portion 30.

The gate runner 48 may be formed of the impurity-doped polysilicon or the like. The gate runner 48 is connected, on the front surface of the semiconductor substrate 10, to the gate conductive portion in the gate trench portion 40. The gate runner 48 is not electrically connected to the dummy conductive portion in the dummy trench portion 30 and the emitter electrode 52.

The gate runner 48 and the emitter electrode 52 are electrically separated by insulators such as the interlayer dielectric film and the oxide film. At the tip portion of the gate trench portion 40, the gate conductive portion is exposed on the front surface of the semiconductor substrate 10 and is connected to the gate runner 48.

The emitter electrode 52 is formed of a conductive material including the metal. For example, the emitter electrode 52 is formed of aluminum or an aluminum-silicon alloy. The emitter electrode 52 may have a barrier metal formed of titanium, a titanium compound, or the like in a lower layer of a region formed of aluminum or the like.

A plating layer (not illustrated) may also be provided on the upper surface of the emitter electrode 52.

The emitter electrode 52 may have the plug formed of tungsten or the like in the contact hole 54. The plug may have the barrier metal on a side in contact with the semiconductor substrate 10, may be formed by embedding tungsten so as to be in contact with the barrier metal, and may be formed of aluminum or the like on the tungsten.

The plug is provided in the contact hole 54 in contact with the contact region 15 or the base region 14. In addition, below the contact hole 54 in which the plug is provided, the P++ type plug region having a higher doping concentration than that of the contact region 15 may be formed. The plug region can improve contact resistance between the barrier metal and the contact region 15. The depth of the plug region may be about 0.1 μm or less, and the plug region may have a region that is as small as 10% or less as compared with the depth of the contact region 15.

By the plug region improving the contact resistance, latch-up tolerance is improved in operation of the transistor portion 70. On the other hand, in operation of the diode portion 80, it is possible to suppress the increase in conduction loss and switching loss.

The well region 11 extends from the gate runner 48 so as to overlap the outer peripheral region 180, and is provided in the annular shape in the top view. The well region 11 also extends with a predetermined width to the active region 160 inside the gate runner 48, and is provided in the annular shape in the top view. The well region 11 of this example is provided in a range separated toward the gate runner 48 side from the end of the contact hole 54 in the Y axis direction. The well region 11 is a second conductivity type region in which the doping concentration is higher than that of the base region 14. The doping concentration of the well region 11 may be the same as the doping concentration of the contact region 15, or may be lower than the doping concentration of the contact region 15. The gate runner 48 is electrically insulated from the well region 11.

In the present example, the base region 14 is the P− type, and the well region 11 is the P+ type. In addition, the well region 11 is formed from the front surface of the semiconductor substrate to a position deeper than a lower end of the base region 14. The base region 14 is provided in contact with the well region 11 in the transistor portion 70 and the diode portion 80. The well region 11 is electrically connected to the emitter electrode 52.

Each of the transistor portion 70 and the diode portion 80 has a plurality of trench portions arranged in the trench arrangement direction. In the transistor portion 70 of this example, one or more gate trench portions 40 and one or more dummy trench portions 30 are alternately provided along the trench arrangement direction. In the diode portion 80 of this example, the plurality of dummy trench portions 30 are provided along the trench arrangement direction.

The gate trench portion 40 of this example may have two extended sections 39 (sections of the trenches that are linear along the trench extending direction) extending along the trench extending direction perpendicular to the trench arrangement direction, and a connection section 41 connecting the two extended sections 39.

At least a part of the connection section 41 may be provided in the curved shape in the top view. The connection section 41 functions as the gate electrode for the gate trench portion 40 by connecting mutual ends of the two extended sections 39 in the Y axis direction to the gate runner 48. On the other hand, by making the connection section 41 curved, it is possible to mitigate electric field concentration at the end as compared with a structure terminated at the extended section 39.

In the transistor portion 70, the dummy trench portion 30 is provided between the respective extended sections 39 of the gate trench portion 40. In the example of FIG. 2, one dummy trench portion 30 is provided between the respective extended sections 39; however, two dummy trench portions 30 may be provided, or more than two dummy trench portions 30 may be provided.

Further, between the respective extended sections 39, the dummy trench portion 30 may not be provided, and the gate trench portion 40 may be provided. With such a structure, since the electron current from the emitter region 12 can be increased, an on-voltage is reduced.

The dummy trench portion 30 may have a linear shape extending in the trench extending direction, and, similarly to the gate trench portion 40, may have the extended section 29 and the connection section 31. The semiconductor device 100 illustrated in FIG. 2 has an arrangement of only the dummy trench portions 30 each having the connection section 31; however, in another example, the semiconductor device 100 may include the linear shaped dummy trench portion 30 having no connection section 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in the top view. That is, at the end in the Y axis direction of each trench portion, the bottom portion in the depth direction (the positive side in the Z axis direction) of each trench portion is covered with the well region 11. With this configuration, the electric field concentration on the bottom portion of each trench portion can be mitigated.

Between each of the trench portions in the trench arrangement direction, the mesa portion 60 is provided. The mesa portion 60 refers to a region sandwiched between the trench portions inside the semiconductor substrate 10. As an example, the depth position of the mesa portion 60 is from the front surface of the semiconductor substrate 10 to a lower end of the trench portion.

The mesa portion 60 of the present example is sandwiched between adjacent trench portions in an X axis direction, and is provided extending along the trench in the trench extending direction (Y axis direction) on a front surface of the semiconductor substrate 10.

Each mesa portion 60 is provided with the base region 14. In each mesa portion 60, at least one of the emitter region 12 of a first conductivity type or the contact region 15 of a second conductivity type may be provided in a region sandwiched between the base regions 14 in the top view. The emitter region 12 in this example is the N+ type, and the contact region 15 is the P+ type. The emitter region 12 and the contact region 15 may be provided between the base region 14 and the front surface of the semiconductor substrate 10 in the depth direction.

The mesa portion 60 of the transistor portion 70 includes the emitter region 12 exposed at the front surface of the semiconductor substrate 10. The emitter region 12 is provided in contact with the gate trench portion 40. In the mesa portion 60 in contact with the gate trench portion 40, the contact region 15 exposed at the front surface of the semiconductor substrate 10 is provided.

Each of the contact region 15 and the emitter region 12 in the mesa portion 60 is provided from one trench portion to another trench portion in the X axis direction. As an example, the contact region 15 and the emitter region 12 in the mesa portion 60 are alternately arranged along the trench extending direction (Y axis direction).

In another example, the contact region 15 and the emitter region 12 of the mesa portion 60 may be provided in stripes along the trench extending direction (Y axis direction). For example, the emitter region 12 is provided in a region in contact with the trench portion, and the contact region 15 is provided in a region sandwiched between the emitter regions 12.

The mesa portion 60 of the diode portion 80 is not provided with the emitter region 12. The base region 14 may be provided on the upper surface of the mesa portion 60 of the diode portion 80. The base region 14 may be arranged over the entirety of the mesa portion 60 of the diode portion 80.

The contact hole 54 is provided above each mesa portion. The contact hole 54 is arranged in a region sandwiched between the base regions 14 in the trench extending direction (Y axis direction). The contact hole 54 of the present example is provided above respective regions of the contact region 15, the base region 14, and the emitter region 12. The contact hole 54 may be arranged at the center of the mesa portion in the trench arrangement direction (X axis direction).

In the diode portion 80, the N+ type cathode region 82 is provided in a region adjacent to the back surface of the semiconductor substrate 10. In the back surface of the semiconductor substrate 10, a region in which the cathode region 82 is not provided may be provided with the collector region 22 of the P+ type. In FIG. 2, a boundary between the cathode region 82 and the collector region 22 is indicated by a dotted line.

The cathode region 82 is arranged separately from the well region 11 in the Y axis direction. Thus, by ensuring a distance between the P type region (the well region 11) having a relatively high doping concentration and being formed to a deep position and the cathode region 82, hole injection from the well region 11 can be suppressed, and therefore reverse recovery loss can be reduced. The end portion in the Y axis direction of the cathode region 82 of this example is arranged farther away from the well region 11 than the end portion in the Y axis direction of the contact hole 54. In another example, the end portion in the Y axis direction of the cathode region 82 may be arranged between the well region 11 and the contact hole 54.

The transistor portion 70 has the boundary region 90 on a side of the adjacent diode portion 80. The boundary region 90 includes a plurality of mesa portions 60. In FIG. 2, the boundary region 90 includes two mesa portions 60, but the boundary region 90 may include more than two mesa portions 60. In the boundary region 90 of this example, a dummy trench portion 30 is provided, and the gate trench portion 40 is not provided.

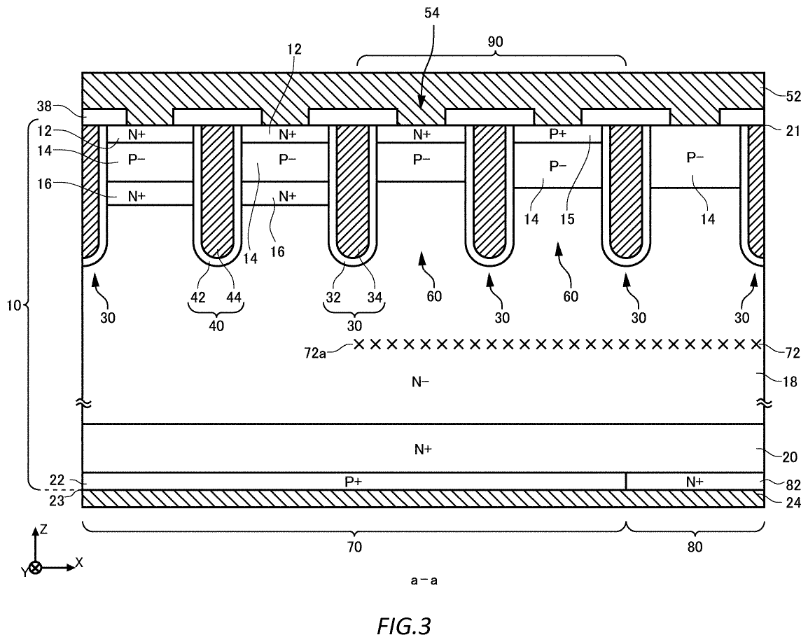

FIG. 3 is a diagram illustrating the cross section a-a of FIG. 2. The cross section a-a is the XZ plane passing through the contact region 15, the base region 14, the gate trench portion 40, and the dummy trench portion 30. The semiconductor device 100 of this example includes, in the cross section a-a, the semiconductor substrate 10, the interlayer dielectric film 38, the emitter electrode 52, and the collector electrode 24.

The interlayer dielectric film 38 is provided on the front surface 21 of the semiconductor substrate 10. The interlayer dielectric film 38 may be the dielectric film such as silicate glass to which an impurity such as boron or phosphorus is added. The interlayer dielectric film 38 may be in contact with the front surface 21, and another film such as the oxide film may be provided between the interlayer dielectric film 38 and the front surface 21 of the semiconductor substrate 10. The interlayer dielectric film 38 is provided with a contact hole 54 described with reference to FIG. 2.

The emitter electrode 52 is provided on the front surface 21 of the semiconductor substrate 10 and an upper surface of the interlayer dielectric film 38. The emitter electrode 52 is electrically connected to the front surface 21 of the semiconductor substrate 10 by the contact hole 54 of the interlayer dielectric film 38. The plug (not illustrated) of tungsten (W) or the like may be embedded in the inside of the contact hole 54 via a barrier metal film. In addition, the P++ type plug region may be provided in a surface layer of the semiconductor substrate 10 in which the contact hole 54 is provided. A doping concentration of the plug region is higher than a doping concentration of the contact region 15.

In addition, the contact hole 54 may be the trench contact in which a bottom portion of the contact hole 54 is provided deeper than the front surface 21 of the semiconductor substrate 10.

The collector electrode 24 is provided on the back surface 23 of the semiconductor substrate 10. The emitter electrode 52 and the collector electrode 24 may be formed of the material including a metal or a laminated film thereof.

The semiconductor substrate 10 may be a silicon substrate, may be a silicon carbide substrate, or may be a nitride semiconductor substrate such as gallium nitride. The semiconductor substrate 10 of this example is the silicon substrate.

The semiconductor substrate 10 has the drift region 18 of a first conductivity type. The drift region 18 of this example is of an N-type. The drift region 18 may be a remaining region in the semiconductor substrate 10 in which other doping regions have not been provided.

Above the drift region 18, one or more accumulation regions 16 may be provided in the Z axis direction. The accumulation region 16 is a region where a same dopant as that of the drift region 18 is accumulated at a higher concentration than the drift region 18. The doping concentration of the accumulation region 16 is higher than the doping concentration of the drift region 18.

The accumulation regions 16 of the present example are of N+ type. The accumulation region 16 may be provided only in the transistor portion 70, or may be provided in both the transistor portion 70 and the diode portion 80. By providing the accumulation region 16, the carrier injection enhancement effect (IE effect) can be increased, and an on-voltage can be reduced. The accumulation region 16 of this example is provided only in the transistor portion 70 and is not provided in the diode portion 80.

In the transistor portion 70, above the base region 14, the emitter region 12 is provided in contact with the front surface 21 of the semiconductor substrate 10. The emitter region 12 is provided in contact with the gate trench portion 40. The doping concentration of the emitter region 12 is higher than the doping concentration of the drift region 18. Dopants of the emitter region 12 are, for example, arsenic (As), phosphorus (P), antimony (Sb), and the like.

In the diode portion 80, the base region 14 exposed at the front surface 21 of the semiconductor substrate 10 is provided. The base region 14 of the diode portion 80 operates as an anode.

The buffer region 20 of a first conductivity type may be provided below the drift region 18. The buffer region 20 of this example is of the N+ type. The doping concentration of the buffer region 20 is higher than the doping concentration of the drift region 18. The buffer region 20 may function as the field stop layer that prevents a depletion layer spreading from the lower surface side of the base region 14 from reaching the collector region 22 and the cathode region 82.

In the transistor portion 70, the collector region 22 is provided below the buffer region 20. The collector region 22 may be provided in contact with the cathode region 82 on the back surface 23 of the semiconductor substrate 10.

In the diode portion 80, the cathode region 82 is provided below the buffer region 20. The cathode region 82 may be provided at the same depth as the collector region 22 of the transistor portion 70. The diode portion 80 may function as the freewheeling diode (FWD) that allows the free wheeling current that conducts in a reverse direction to flow when the transistor portion 70 turns off.

The gate trench portion 40 and the dummy trench portion 30 are provided in the semiconductor substrate 10. The gate trench portion 40 and the dummy trench portion 30 are provided so as to pass through the base region 14 and the accumulation region 16 from the front surface 21 of the semiconductor substrate 10 and reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 includes a gate trench provided in the front surface 21 of the semiconductor substrate 10, a gate dielectric film 42, and a gate conductive portion 44. The gate dielectric film 42 is provided to cover the inner wall of the gate trench. The gate dielectric film 42 may be formed of the oxide film or the nitride film. The gate conductive portion 44 is provided to be embedded on an inner side further than the gate dielectric film 42 inside the gate trench. The upper surface of the gate conductive portion 44 may be in the same XY plane as the front surface 21 of the semiconductor substrate 10. The gate dielectric film 42 insulates the gate conductive portion 44 from the semiconductor substrate 10. The gate conductive portion 44 may be formed of polysilicon or the like doped with impurities.

The gate conductive portion 44 may be provided to be longer than the base region 14 in the depth direction. The gate trench portion 40 is covered by the interlayer dielectric film 38 on the front surface 21 of the semiconductor substrate 10. When a predetermined voltage is applied to the gate conductive portion 44, a channel due to an electron inversion layer is formed in a surface layer of the boundary in direct contact with the gate trench in the base region 14.

The dummy trench portions 30 may have the same structure as the gate trench portions 40 in the XZ cross section. The dummy trench portion 30 includes a dummy trench provided in the front surface 21 of the semiconductor substrate 10, a dummy dielectric film 32, and a dummy conductive portion 34. The dummy dielectric film 32 is provided covering an inner wall of the dummy trench. The dummy dielectric film 32 may be formed of the oxide film or the nitride film. The dummy conductive portion 34 is provided so as to fill an inside of the dummy trench on an inner side of the dummy dielectric film 32. The upper surface of the dummy conductive portion 34 may be in the same XY plane as the front surface 21 of the semiconductor substrate 10. The dummy dielectric film 32 insulates the dummy conductive portion 34 from the semiconductor substrate 10. The dummy conductive portion 34 may be formed of the same material as the gate conductive portion 44.

The gate trench portion 40 and the dummy trench portion 30 of this example are covered with the interlayer dielectric film 38 on the front surface 21 of the semiconductor substrate 10. It is noted that the bottoms of the dummy trench portion 30 and the gate trench portion 40 may be formed in a curved-surface shape (a curved-line shape in the cross section) convexly downward.

In the diode portion 80, a lifetime control region 72 including a lifetime killer is locally provided in the drift region 18. The lifetime killer is the crystal defect formed at a predetermined depth position of the semiconductor substrate 10 by implanting, for example, helium ions, hydrogen ions (protons or deuterons), or the like. The lifetime control region 72 promotes recombination between holes generated in the base region 14 at turn-off of the diode portion 80 and electrons injected from the cathode region 82, and suppresses a peak current at reverse recovery.

The lifetime control region 72 may be formed by performing irradiation with the proton or helium particle beam from the front surface 21 or the back surface 23 of the semiconductor substrate 10 using a mask. As an example, the transistor portion 70 and the diode portion 80 are irradiated with the proton or helium particle beam through an opening portion of the resist mask in a state in which a region where the lifetime control region 72 is not to be formed is shielded by the resist mask formed above the front surface 21 of the semiconductor substrate 10. The region shielded by the mask is not irradiated with the proton or helium particle beam.

In FIG. 3, peak positions in the Z axis direction of the concentration distribution of the lifetime killer are indicated by a symbol of “x”. The peak position in the Z axis direction of the lifetime control region 72 of this example may be equal to the position in the Z axis direction of the lower surface of the well region 11, or may be provided below the position in the Z axis direction of the lower surface of the well region 11. The lifetime control region 72 may be formed to have a plurality of peaks of the concentration distribution of the lifetime killer in the Z axis direction.

The lifetime control region 72 of this example is continuously provided on the front surface 21 side of the semiconductor substrate 10 over at least a part of the transistor portion 70 from the diode portion 80. In the transistor portion 70, a region in which the lifetime control region 72 is provided is referred to as the boundary region 90. During conduction of the diode portion 80, the hole current is generated not only in the base region 14 of the diode portion 80, but also the hole current is generated from the base region 14 of the transistor portion 70 toward the cathode region 82. The transistor portion 70 promotes carrier extinction and reduces reverse recovery loss at turn-off by having the boundary region 90 in which the lifetime control region 72 is provided.

However, in the trench portion of the boundary region 90, when the gate dielectric film 42 is irradiated with the helium or proton particle beam from the front surface 21 or the back surface 23 of the semiconductor substrate 10, the gate dielectric film 42 is damaged and the interface state changes. When the gate voltage is applied to the irradiated gate dielectric film 42, an inversion layer is more easily formed in the adjacent base region 14 than in the gate dielectric film 42 that is not irradiated. Therefore, in the boundary region 90, the threshold voltage decreases as compared with a region other than the boundary region 90 of the transistor portion 70. Therefore, in the boundary region 90 of this example, the dummy trench portion 30 is provided, and the gate trench portion 40 is not provided. In addition, in the boundary region 90 of this example, an accumulation region 16 is not provided.

Note that the end 72a of the lifetime control region 72 only needs to be within the boundary region 90, and it is not necessary to provide the lifetime control region 72 over the entire surface of the boundary region 90.

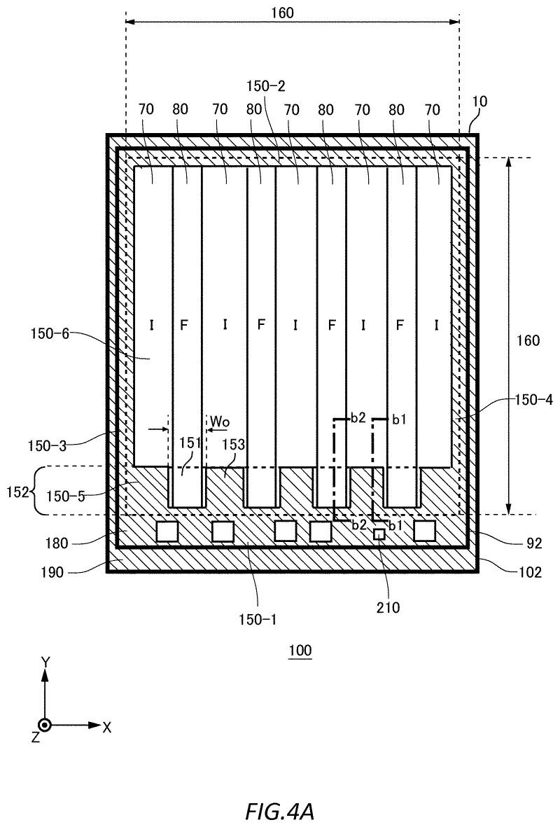

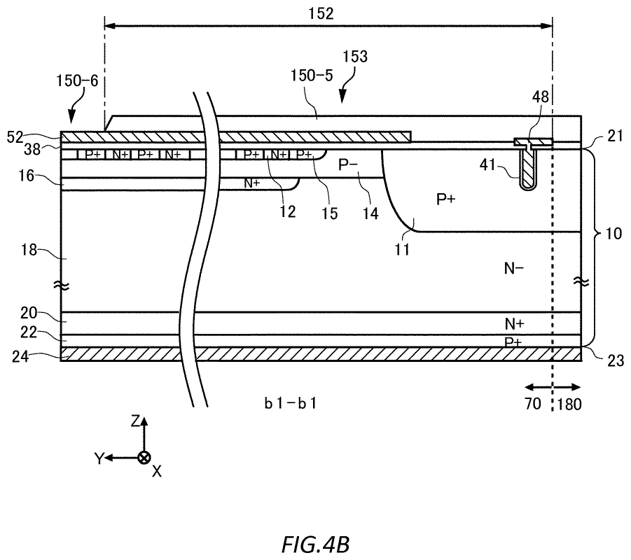

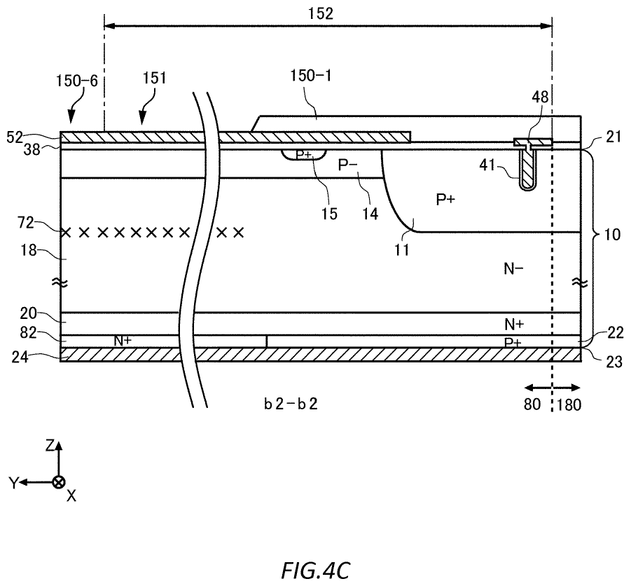

FIG. 4A is the top view illustrating an arrangement example of the protective layer 150. In FIG. 4A, a region in which the protective layer 150 is arranged is indicated by hatched shading. The protective layer 150 may be provided above the emitter electrode 52. The protective layer 150 may be provided above the semiconductor substrate 10. That is, the protective layer 150 may be provided above the semiconductor substrate 10 in the region in which the emitter electrode 52 is not formed. The protective layer 150 may be in contact with the upper surface of the emitter electrode 52.

The protective layer 150 of this example has outer peripheral protective portions 150-1 to 150-4 provided above the outer peripheral region 180. In FIG. 4A, of the protective layer 150, a region provided above the auxiliary pad is defined as an outer peripheral protective portion 150-1, and a region facing the outer peripheral protective portion 150-1 is defined as an outer peripheral protective portion 150-2. The outer peripheral protective portion 150-1 and the outer peripheral protective portion 150-2 may be provided so as to extend in parallel with the end side 102 extending in the X axis direction. The outer peripheral protective portion 150-3 and the outer peripheral protective portion 150-4 may be provided so as to face each other and extend in the Y axis direction. The outer peripheral protective portion 150-1 may have an opening portion that exposes a part of the upper surface of the auxiliary pad. Thus, the wire or the like can be connected to the upper surface of the auxiliary pad.

The protective layer 150 of this example has the central opening portion 150-6 that exposes a part of the upper surface of the emitter electrode 52. The central opening portion 150-6 is surrounded by the outer peripheral protective portions 150-1 to 150-4. By providing the central opening portion 150-6, wiring such as the lead frame can be connected to the upper surface of the emitter electrode 52 via a bonding material such as solder. Note that the wiring may be connected by performing wire bonding to connect the wire.

The protective layer 150 of this example has an end-side protective portion 150-5 provided adjacent to an end in the Y axis direction of the transistor portion 70 and the diode portion 80. In the example of FIG. 4A, a plurality of end-side protective portions 150-5 are arranged in the X axis direction. In this example, a plurality of protective regions 153 in which the end-side protective portions 150-5 are provided and a plurality of opening regions 151 in which the end-side protective portions 150-5 are not provided constitute a protective structure 152. The protective structure 152 is provided between the central opening portion 150-6 and the outer peripheral protective portion 150-1. In the protective structure 152, the plurality of protective regions 153 and the plurality of opening regions 151 are alternately provided in the X axis direction.

Each end-side protective portion 150-5 is provided in the transistor portion 70. The end-side protective portion 150-5 of this example is provided in contact with the outer peripheral protective portion 150-1 provided above the auxiliary pad in the Y axis direction. The end in the X axis direction of the end-side protective portion 150-5 is provided in the boundary region 90. That is, the end-side protective portion 150-5 is not provided in the diode portion 80. The width in the X axis direction of the end-side protective portion 150-5 is equal to or less than the width in the X axis direction of the transistor portion 70.

Each opening region 151 is provided in the diode portion 80. The width Wo in the X axis direction of the opening region 151 may be 400 μm or more and 800 μm or less. The width Wo in the X axis direction of the opening region 151 is smaller than the width in the X axis direction of the protective region 153. The width Wo in the X axis direction of the opening region 151 may be larger than the width in the X axis direction of the diode portion 80. The opening region 151 may extend in the X axis direction over at least a part of the boundary region 90 adjacent to the diode portion 80 from the diode portion 80. That is, the opening region 151 may be provided so as to correspond to the lifetime control region 72. The opening region 151 exposes a part of the upper surface of the emitter electrode 52. The opening region 151 may be connected to the central opening portion 150-6 in the Y axis direction.

FIG. 4B is a diagram illustrating the cross section b1-b1 of FIG. 4A. FIG. 4C is a diagram illustrating the cross section b2-b2 of FIG. 4A. The cross section b1-b1 of FIG. 4B is the YZ plane passing through the protective region 153 of the transistor portion 70 along the Y axis direction, and the cross section b2-b2 of FIG. 4C is the YZ plane passing through the opening region 151 of the diode portion 80 along the Y axis direction.

The lifetime control region 72 of this example is not formed in the transistor portion 70 other than the boundary region 90. Therefore, in a state in which the transistor portion 70 in which the lifetime control region 72 is not formed is shielded by a resist mask formed above the front surface 21 of the semiconductor substrate 10, the diode portion 80 and the boundary region 90 are irradiated with the proton or helium particle beam through the opening portion of the resist mask. As a result, the proton or helium particle beam does not pass through the transistor portion 70 other than the boundary region 90, and it is possible to suppress variation in threshold voltage. On the other hand, as illustrated in FIG. 4C, the lifetime control region 72 is formed in the diode portion 80 that is not shielded by the resist mask.

In the conventional semiconductor device, in order to prevent solder for arranging a lead frame on an upper surface of the emitter electrode exposed by a central opening portion of a protective layer from spreading to an auxiliary pad, the protective layer was extended from above the auxiliary pad toward the active region 160 side and was provided up to above the transistor portion and the diode portion. Therefore, in a region of the diode portion 80 in which the protective layer is provided, the implantation depth of the proton or helium particle beam becomes shallower than in a region in which the protective layer is not provided, and a peak concentration position of the lifetime control region becomes shallower.

The semiconductor device of this example includes the protective structure 152 in which the protective region 153 and the opening region 151 are alternately provided, and by causing the opening region 151 to correspond to a range of the lifetime control region 72, it is possible to perform irradiation with the proton or helium particle beam without being shielded by the protective layer and to keep a peak concentration position of the lifetime control region constant.

In addition, since the width of the protective region 153 is larger than the width Wo of the opening region 151, according to the protective structure 152 of this example, it is possible to prevent solder spreading from the central opening portion 150-6 from reaching the auxiliary pad.

Furthermore, since the end-side protective portion 150-5 and the protective region 153 extend in the Y axis direction to the active region 160, it is possible to prevent solder spreading from the central opening portion 150-6 from reaching the auxiliary pad without the lifetime control region 72 being shielded by the protective layer.

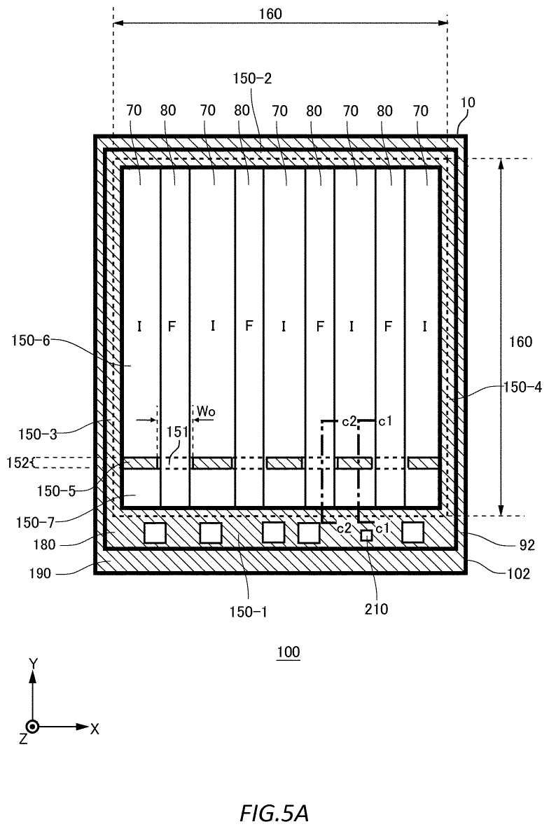

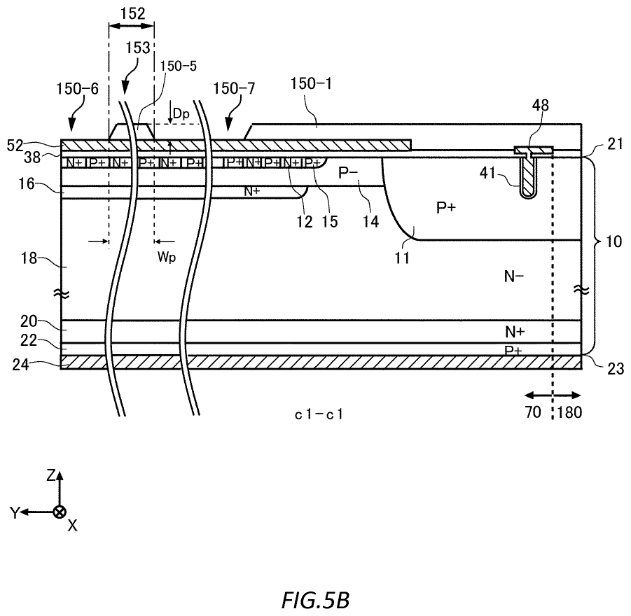

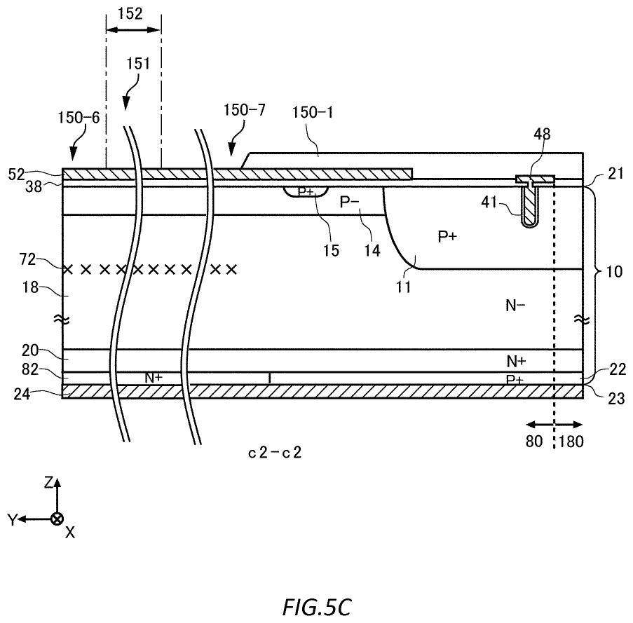

FIG. 5A is the top view illustrating another arrangement example of the protective layer 150. Here, the same reference numerals are assigned to elements common to those in FIG. 4A, and description thereof is omitted. The protective layer 150 illustrated in FIG. 5A has the end-side opening portion 150-7 that exposes a part of the upper surface of the emitter electrode 52 between the protective structure 152 and the outer peripheral protective portion 150-1. The end-side protective portion 150-5 of the protective structure 152 is provided between the central opening portion 150-6 and the end-side opening portion 150-7. That is, the end-side protective portion 150-5 of this example, unlike the example of FIG. 4A, is spaced apart from the outer peripheral protective portion 150-1 provided above the auxiliary pad.

FIG. 5B is a diagram illustrating the cross section c1-c1 of FIG. 5A. FIG. 5C is a diagram illustrating the cross section c2-c2 of FIG. 5A. The cross section c1-c1 of FIG. 5B is the YZ plane that passes through the protective region 153 of the transistor portion 70 along the Y axis direction, and the cross section c2-c2 of FIG. 5C is the YZ plane that passes through the opening region 151 of the diode portion 80 along the Y axis direction.

As illustrated in FIG. 5B, the end-side protective portion 150-5 of the protective region 153 has a trapezoidal cross section. A width Wp of the end-side protective portion 150-5 in the Y axis direction may be 30 μm or more and 90 μm or less. The thickness Dp of the end-side protective portion 150-5 may be 5 μm or more and 15 μm or less. The end-side protective portion 150-5 of the protective region 153 can have the thickness Dp sufficient to block solder spreading from the central opening portion 150-6 by having the width Wp in such a range. In addition, by providing the end-side opening portion 150-7 between the end-side protective portion 150-5 and the outer peripheral protective portion 150-1, warpage of the chip can be suppressed.

In addition, the end-side protective portion 150-5 may increase the distance to be spaced apart from the outer peripheral protective portion 150-1 in the Y axis direction. This makes it easier to block the solder spreading from the central opening portion 150-7.

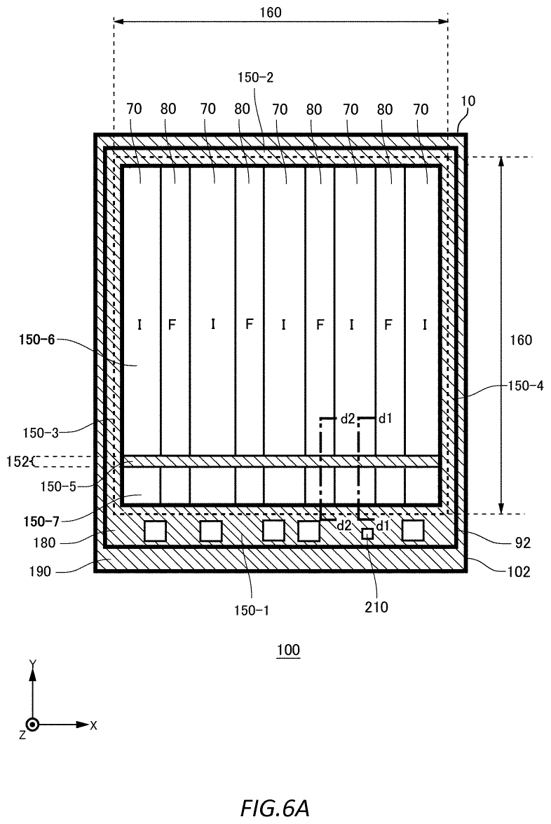

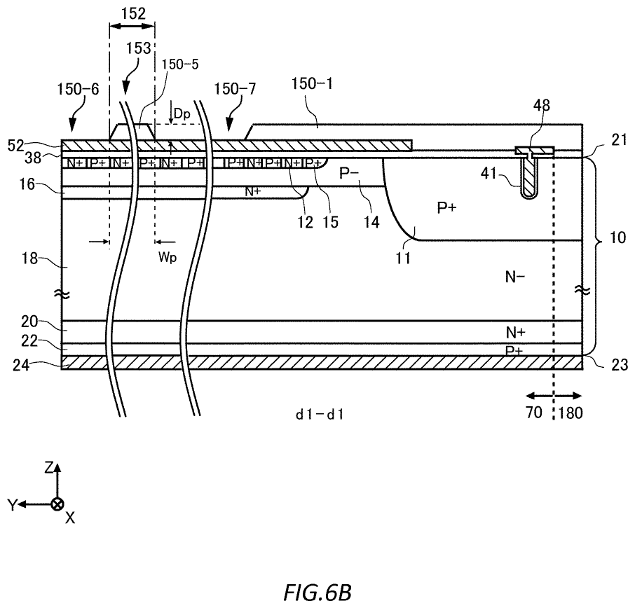

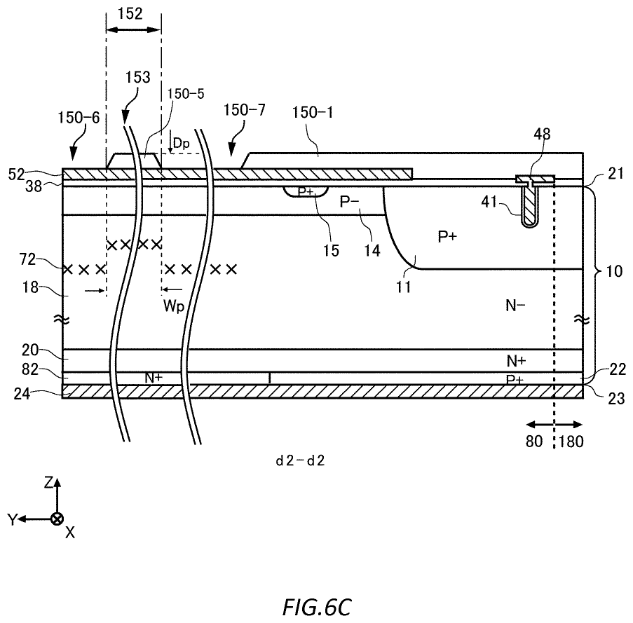

FIG. 6A is the top view illustrating another arrangement example of the protective layer 150. Here, the same reference numerals are assigned to elements common to those in FIG. 5A, and description thereof is omitted. The protective structure 152 illustrated in FIG. 6A has no opening region and has only the protective region 153 in which the end-side protective portion 150-5 is provided. The end-side protective portion 150-5 of this example extends in the X axis direction across the active region 160. The end-side protective portion 150-5 of this example is provided in the Y axis direction in proximity to the end side on which an auxiliary pad is provided.

FIG. 6B is a diagram illustrating the cross section d1-d1 of FIG. 6A. FIG. 6C is a diagram illustrating the cross section d2-d2 of FIG. 6A. The cross section d1-d1 of FIG. 6B is the YZ plane that passes through the protective region 153 of the transistor portion 70 along the Y axis direction, and the cross section d2-d2 of FIG. 6C is the YZ plane that passes through the protective region 153 of the diode portion 80 along the Y axis direction. This example differs from the examples of FIG. 4A and FIG. 5A in that the end-side protective portion 150-5 is also provided in the diode portion 80 in which the lifetime control region 72 is formed.

As described above, in the region in which the protective layer 150 is provided, the implantation depth of the helium or proton particle beam is shallower than that in the region in which the protective layer 150 is not provided, and the peak concentration position of the lifetime control region becomes shallower. As illustrated in FIG. 6C, the peak concentration position of the lifetime control region 72 below the end-side protective portion 150-5 is shallower than the peak concentration position of the lifetime control region 72 in a region (the central opening portion 150-6 and the end-side opening portion 150-7) of the diode portion 80 in which the end-side protective portion 150-5 is not provided.

As in the example of FIG. 5A, the width Wp of the end-side protective portion 150-5 in the Y axis direction may be 30 μm or more and 90 μm or less, and the thickness Dp of the end-side protective portion 150-5 may be 5 μm or more and 15 μm or less. Since the end-side protective portion 150-5 of this example is also provided in the diode portion 80, variation occurs in the peak concentration position of the lifetime control region 72 formed in the diode portion 80. However, since the width Wp of the end-side protective portion 150-5 is sufficiently small with respect to the dimension of the element, solder spreading from the central opening portion 150-6 can be blocked while minimizing an influence on characteristics of the diode portion 80.

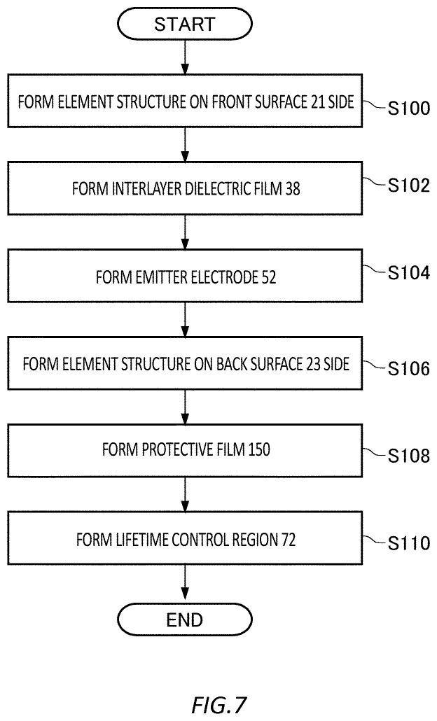

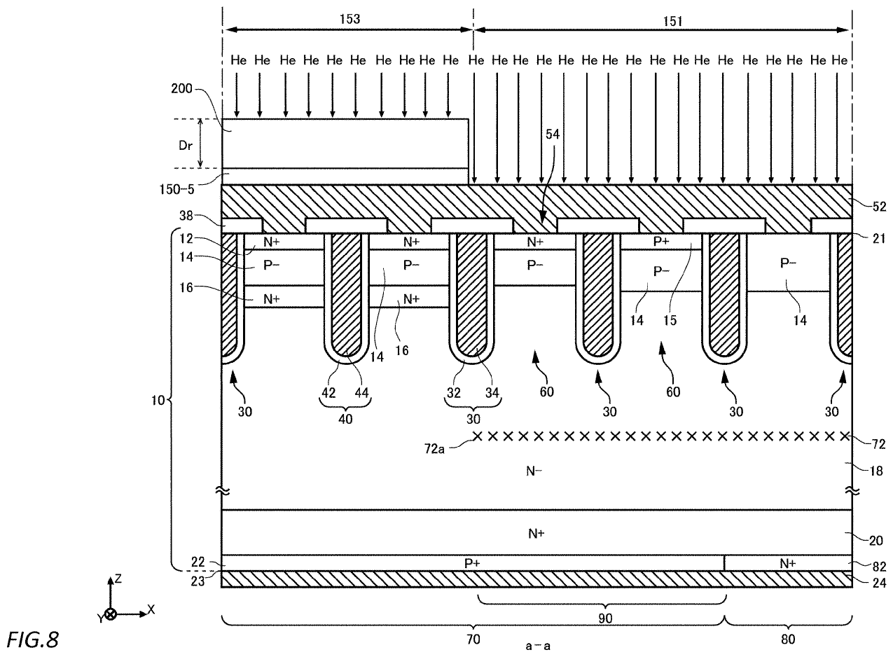

FIG. 7 is a flowchart illustrating an example of the manufacturing process of the semiconductor device 100. FIG. 8 is a diagram illustrating an example in which step S110 of FIG. 7 is applied to the cross section a-a of FIG. 2. Here, as the semiconductor device 100, an example of the manufacturing process of the RC-IGBT having a withstand voltage of 1200 V will be described.

In step S100, the element structure on the front surface 21 side of the semiconductor substrate 10 is formed. Here, as the semiconductor substrate 10, the low-resistivity P type silicon wafer is used. By implanting impurities from the front surface 21 of the semiconductor substrate 10 and thermally diffusing the impurities, the emitter region 12 and the like are formed. Step S100 may include a step of forming, by ion implantation into the semiconductor substrate 10, the base region 14, the emitter region 12, the contact region 15, and the like as the element structure on the front surface 21 side of the semiconductor substrate 10. Step S100 may include a step of forming the dummy trench portion 30 and the gate trench portion 40 as the element structure on the front surface 21 side.

In step S102, the interlayer dielectric film 38 is formed above the front surface 21 of the semiconductor substrate 10. The interlayer dielectric film 38 may be a silicon oxide film such as BPSG. The interlayer dielectric film 38 may be formed by stacking a plurality of dielectric films. Step S102 may include a step of forming the contact hole by etching the interlayer dielectric film 38.

In step S104, the emitter electrode 52 is formed above the front surface 21 of the semiconductor substrate 10. For example, aluminum or an alloy containing aluminum as a main component (for example, an aluminum-silicon alloy, an aluminum-silicon-copper alloy, or the like) may be deposited on the front surface 21 of the semiconductor substrate 10 and on the interlayer dielectric film 38, and the emitter electrode 52 may be formed.

Step S104 may also include a step of forming the barrier metal between the interlayer dielectric film 38 and the emitter electrode 52. Step S104 may also include a step of embedding, in the contact hole via the barrier metal, the plug made of tungsten or the like.

Step S104 may also include a step of forming the plating layer on the emitter electrode 52.

In step S106, the element structure on the back surface 23 side of the semiconductor substrate 10 is formed. Step S106 may include a step of, after setting the semiconductor substrate 10 to the desired thickness by back grinding, forming the buffer region 20, the collector region 22, the cathode region 82, and the like by ion implantation into the semiconductor substrate 10.

In step S108, the protective layer 150 is formed above the front surface 21 of the semiconductor substrate 10. The protective layer 150 is patterned so as to have the protective structure 152 described with reference to FIGS. 4A, 5A, and 6A. The protective layer 150 of this example is polyimide. After spin-coating and curing polyimide applied to the upper surface of the emitter electrode 52, the protective layer 150 may be formed by removing polyimide in the opening region 151, the central opening portion 150-6, and the end-side opening portion 150-7.

In step S110, in the diode portion 80 and the boundary region 90, the lifetime control region 72 is formed by performing irradiation with a proton or helium particle beam from the front surface 21 side of the semiconductor substrate 10. The end 72a of the lifetime control region 72 only needs to be formed within the boundary region 90.

In this example, the resist 200 is arranged above the protective layer 150, and irradiation is performed with helium ions by using the resist 200 as the mask. The resist 200 is arranged in the transistor portion 70. In this example, the implantation depth of helium ions is about 17 μm, and the film thickness Dr of the resist 200 is 30 μm or more and 70 μm or less. After formation of the lifetime control region 72, the resist 200 may be removed by ashing and stripping processes.

While the present invention has been described by way of the embodiments, the technical scope of the present invention is not limited to the above-described embodiments. It is apparent to persons skilled in the art that various alterations or improvements can be added to the above-described embodiments. It is also apparent from the described scope of the claims that the embodiments added with such alterations or improvements can be included in the technical scope of the present invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate; 11: well region; 12: emitter region; 14: base region; 15: contact region; 16: accumulation region; 18: drift region; 20: buffer region; 21: front surface; 22: collector region; 23: back surface; 24: collector electrode; 25: connection portion; 29: extended section; 30: dummy trench portion; 31: connection section; 32: dummy dielectric film; 34: dummy conductive portion; 38: interlayer dielectric film; 40: gate trench portion; 39: extended section; 42: gate dielectric film; 41: connection section; 44: gate conductive portion; 48: gate runner; 52: emitter electrode; 54: contact hole; 56: contact hole; 60: mesa portion; 70: transistor portion; 72: lifetime control region; 72a: end; 80: diode portion; 82: cathode region; 90: boundary region; 92: guard ring; 100: semiconductor device; 102: end side; 150: protective layer; 151: opening region; 152: protective structure; 153: protective region; 160: active region; 180: outer peripheral region; 190: edge termination region; 200: resist; 210: current sensing portion.

What is claimed is:

1. A semiconductor device comprising:
a plurality of transistor portions and a plurality of diode portions alternately arranged;
a plurality of trench portions extending in a predetermined trench extending direction on a front surface of a semiconductor substrate;
an emitter electrode provided above the front surface of the semiconductor substrate; and
a protective layer provided above the emitter electrode, wherein
the semiconductor device comprises a protective structure in which a plurality of protective regions in which the protective layer is provided and a plurality of opening regions in which the protective layer is not provided are alternately provided.

2. The semiconductor device according to claim 1, wherein
a width of each opening region of the plurality of opening regions is 400 μm or more and 800 μm or less.

3. The semiconductor device according to claim 1, wherein a thickness of the protective layer is 5 μm or more and 15 μm or less.

4. The semiconductor device according to claim 1, wherein
a width, in the trench extending direction, of the protective layer of the protective structure is 30 μm or more and 90 μm or less.

5. The semiconductor device according to claim 1, comprising:
a lifetime control region provided on a front surface side of the semiconductor substrate, wherein
each transistor portion of the plurality of transistor portions has a boundary region on an adjacent diode portion side, and the lifetime control region extends from each diode portion of the plurality of diode portions to an adjacent boundary region, and
the boundary region includes a plurality of mesa portions.

6. The semiconductor device according to claim 5, wherein
an end of the protective layer is provided in the boundary region.

7. The semiconductor device according to claim 6, wherein
the protective layer is not provided in the plurality of diode portions.

8. The semiconductor device according to claim 1, wherein
each opening region of the plurality of opening regions is provided in each diode portion of the plurality of diode portions.

9. The semiconductor device according to claim 8, wherein
the protective layer has an outer peripheral protective portion provided above an outer peripheral region of the semiconductor substrate, and
the protective layer of the protective structure is in contact with the outer peripheral protective portion in which an auxiliary pad is provided on an inner side in a top view of the semiconductor substrate.

10. The semiconductor device according to claim 8, wherein
the protective layer has an outer peripheral protective portion provided above an outer peripheral region of the semiconductor substrate, and
the protective layer of the protective structure is spaced apart from the outer peripheral protective portion in which an auxiliary pad is provided on an inner side in a top view of the semiconductor substrate.

11. The semiconductor device according to claim 1, comprising:
an auxiliary pad provided between an end, in the trench extending direction, of the plurality of transistor portions and the plurality of diode portions and an end side of the semiconductor substrate, wherein
the protective layer has an outer peripheral protective portion provided above an outer peripheral region of the semiconductor substrate, and the auxiliary pad is provided on an inner side of the outer peripheral protective portion in a top view of the semiconductor substrate, and
the protective structure is provided between a central opening portion that exposes a part of an upper surface of the emitter electrode and the outer peripheral protective portion.

12. The semiconductor device according to claim 11, wherein
the protective structure is provided at the end, in the trench extending direction, of the plurality of transistor portions and the plurality of diode portions.

13. The semiconductor device according to claim 11, wherein
the protective layer is provided with an end-side opening portion that exposes a part of the upper surface of the emitter electrode between the protective structure and the outer peripheral protective portion.

14. A semiconductor device comprising:
a plurality of transistor portions and a plurality of diode portions alternately arranged in a predetermined element arrangement direction,
an emitter electrode provided above a front surface of a semiconductor substrate, and
a protective layer provided above the emitter electrode, wherein
the protective layer extends in the element arrangement direction across the plurality of transistor portions and the plurality of diode portions.

15. The semiconductor device according to claim 14, comprising:
an auxiliary pad provided between an end, in a predetermined element extending direction, of the plurality of transistor portions and the plurality of diode portions and a first end side of the semiconductor substrate, wherein
the protective layer is provided closer to the first end side than to a second end side facing the first end side in the element extending direction.

16. The semiconductor device according to claim 15, wherein
the plurality of diode portions have lifetime control regions having different peak concentration depths.

17. The semiconductor device according to claim 16, wherein
a peak concentration position of the lifetime control region below the protective layer is shallower than a peak concentration position of the lifetime control region in a region in which the protective layer is not provided.

18. The semiconductor device according to claim 14, comprising:
an auxiliary pad provided between an end, in a predetermined element extending direction, of the plurality of transistor portions and the plurality of diode portions and an end side of the semiconductor substrate, wherein
the protective layer has
an end-side protective portion extending in the element arrangement direction across the plurality of transistor portions and the plurality of diode portions,
an outer peripheral protective portion provided above an outer peripheral region of the semiconductor substrate and in which the auxiliary pad is provided on an inner side in a top view of the semiconductor substrate,
a central opening portion that exposes a part of an upper surface of the emitter electrode, and
an end-side opening portion that is adjacent to the outer peripheral protective portion and is smaller than the central opening portion, and
the end-side protective portion is provided between the central opening portion and the end-side opening portion.
